(19) United States
(12) Patent Application Publication
(10) Pub. No.: US 2025/0157107 A1
(43) Pub. Date: May 15, 2025

(54) DEVICE AND METHOD FOR EXTRACTING INFORMATION IN DESIGN DRAWING

(71) Applicants: HYUNDAI MOTOR COMPANY, Seoul (KR); Kia Corporation, Seoul (KR)

(72) Inventor: Taewoo KANG, Hwaseong-si (KR)

(21) Appl. No.: 18/945,231

(22) Filed: Nov. 12, 2024

(30) Foreign Application Priority Data
Nov. 13, 2023 (KR) 10-2023-0156151

(51) Int. Cl. G06T 11/60; G06F 30/15

(52) U.S. Cl. CPC G06T 11/60; G06F 30/15

(57) ABSTRACT

A device and a method for extracting information in a design drawing are provided. A device for extracting information in a design drawing may include a vehicle design drawing input module that receives a design drawing of a vehicle in the form of an image, a first type table extracting module that extracts first type tables from the design drawing, and a first type table duplication removal module that detects child tables corresponding to child relationships with the first type tables, from the extracted first type tables, and remove the child tables as duplicated tables.

### CROSS-REFERENCE TO RELATED APPLICATION

This application claims priority to and the benefit of Korean Patent Application No. 10-2023-0156151 filed in the Korean Intellectual Property Office on Nov. 13, 2023, the entire contents of which are incorporated herein by reference.

### TECHNICAL FIELD

The present disclosure relates to a device and a method for extracting information in a design drawing.

### BACKGROUND

Vehicle design drawings show the parts and systems of vehicles, providing information for manufacturing, assembling, maintaining, and repairing the vehicles. Examples of vehicle design drawings include assembly drawings, part drawings, wiring diagrams, body drawings, structural drawings, etc.

An assembly drawing shows how various parts fit together to form a system, detailing the assembly of complex components such as the engine, transmission, brake system, and electrical system.

A part drawing details individual parts, specifying their shapes, sizes, materials, surface finishes, and other characteristics.

A wiring diagram relates to the vehicle's electrical system, illustrating the arrangement and connection of components such as headlights, signal lights, sensors, the battery, generator, and starter.

A body drawing relates to vehicle's exterior, body, and interior, while a structural drawing shows the vehicle's structural elements, such as the frame, suspension system, bearings, and axles.

### SUMMARY

The present disclosure is directed to a device and a method for extracting information in a drawing and capable of extracting desired information from a design drawing of a vehicle.

A device for extracting information in a design drawing can include a vehicle design drawing input module that receives a design drawing of a vehicle in the form of an image, a first type table extracting module that extracts first type tables from the design drawing, and a first type table duplication removal module that detects child tables corresponding to child relationships with the first type tables, from the extracted first type tables, and remove the child tables as duplicated tables.

In some implementations, the first type table duplication removal module may designate a plurality of measurement points in an image of each of the extracted first type tables, designate a plurality of single table areas based on the plurality of measurement points, and detect the child tables by checking the extracted first type tables using the plurality of single table areas.

In some examples, the first type table duplication removal module may check each of the plurality of single table areas for identicalness while vertically or horizontally moving them on another extracted first type table, and determine another extracted first type table as the child table when identicalness is maintained until the number of movements reaches a predetermined value.

In some implementations, the first type table duplication removal module may designate a plurality of crop areas obtained by cropping the plurality of single table areas at a predetermined ratio, and detect the child tables by checking the extracted first type tables using the plurality of crop areas.

In some examples, the first type table duplication removal module may check the plurality of crop areas for identicalness while vertically or horizontally moving them on another extracted first type table, and determine another extracted first type table as the child table when identicalness is maintained until the number of movements reaches a predetermined value.

In some implementations, the plurality of crop areas may have a size obtained by cropping the plurality of single table areas at the ratio of one-third.

In some examples, the device for extracting information in the design drawing may further include a note area extracting module that extracts note areas from the design drawing.

In some implementations, the note area extracting module may extract the note areas by repeatedly using an erode kernel and a dilate kernel on areas in the design drawing where text is written.

In some examples, the device for extracting information in the design drawing may further include a second type table extracting module that extracts second type tables shared with the outermost edge line of at least one modification design drawing, from the design drawing on which the first type table extraction has been completed.

In some implementations, when a plurality of second type tables sharing the outermost edge line is extracted, the second type table extracting module may extract them into one or separately depending on whether the height differences of them exceeds a predetermined value.

A method for extracting information in a design drawing can include a step of receiving a design drawing of a vehicle in the form of an image, a step of extracting first type tables from the design drawing, and a step of detecting child tables corresponding to child relationships with the first type tables, from the extracted first type tables, and removing the child tables as duplicated tables.

In some implementations, the step of removing the child tables as duplicated tables may include a step of designating a plurality of measurement points in an image of each of the extracted first type tables, a step of designating a plurality of single table areas based on the plurality of measurement points, and a step of detecting the child tables by checking the extracted first type tables using the plurality of single table areas.

In some examples, the step of removing the child tables as duplicated tables may include a step of checking each of the plurality of single table areas for identicalness while vertically or horizontally moving them on another extracted first type table, and a step of determining another extracted first type table as the child table when identicalness is maintained until the number of movements reaches a predetermined value.

In some implementations, the step of removing the child tables as duplicated tables may include a step of designating a plurality of crop areas obtained by cropping the plurality of single table areas at a predetermined ratio, and a step of detecting the child tables by checking the extracted first type tables using the plurality of crop areas.

In some examples, the step of removing the child tables as duplicated tables may include a step of checking the plurality of crop areas for identicalness while vertically or horizontally moving them on another extracted first type table, and a step of determining another extracted first type table as the child table when identicalness is maintained until the number of movements reaches a predetermined value.

In some implementations, the plurality of crop areas may have a size obtained by cropping the plurality of single table areas at the ratio of one-third.

In some examples, the method for extracting information in the design drawing may further include a step of extracting note areas from the design drawing.

In some implementations, the step of extracting the note areas may include a step of extracting the note areas by repeatedly using an erode kernel and a dilate kernel on areas in the design drawing where text is written.

In some examples, the method for extracting information in the design drawing may further include a step of extracting second type tables shared with the outermost edge line of at least one modification design drawing, from the design drawing on which the first type table extraction has been completed.

In some implementations, the step of extracting the second type tables may include a step of extracting a plurality of second type tables sharing the outermost edge line into one or separately depending on whether the height differences of them exceed a predetermined value, when they are extracted.

### BRIEF DESCRIPTION OF THE DRAWINGS

FIG. 1 is a block diagram illustrating an example of a device for extracting information in a design drawing.

FIGS. 2 to 8 are diagrams illustrating an example of operations performed by a first type table extracting module.

FIG. 9 is a diagram illustrating an example of an operation performed by a note area extracting module.

FIGS. 10 and 11 are diagrams illustrating an example of an operation performed by a second type table extracting module.

FIG. 12 is a flow chart illustrating an example of a method for extracting information from a design drawing.

FIG. 13 is a diagram illustrating an example of a computing device.

### DETAILED DESCRIPTION

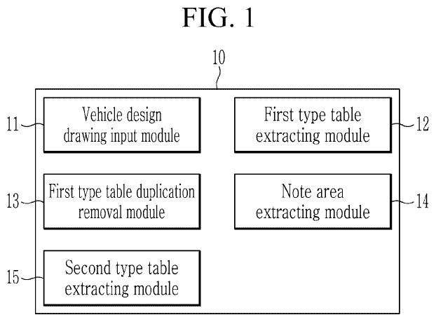

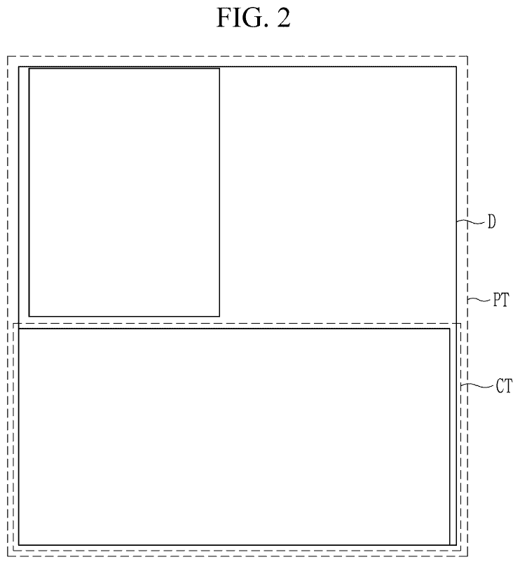

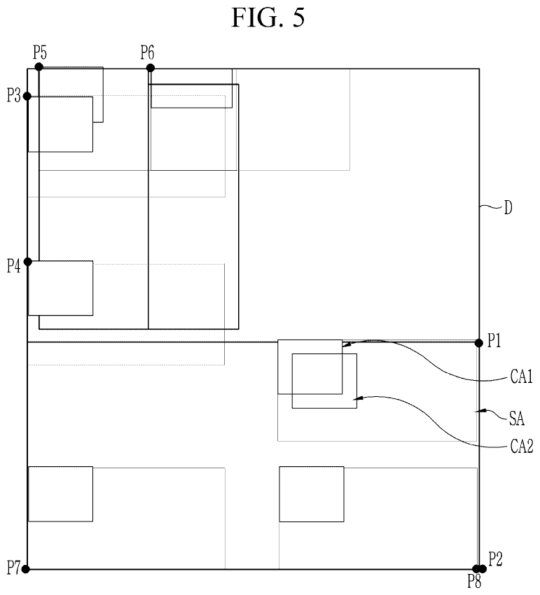

FIG. 1 is a block diagram illustrating an example of a device for extracting information in a design drawing, and FIGS. 2 to 8 are diagrams illustrating an example of operations performed by a first type table extracting module.

Referring to FIG. 1, a device 10 for extracting information in a design drawing can include a vehicle design drawing input module 11, a first type table extracting module 12, a first type table duplication removal module 13, a note area extracting module 14, and a second type table extracting module 15.

The vehicle design drawing input module 11 can receive design drawings of vehicles in the form of images. For example, vehicle design drawings show vehicle's parts and systems and provide information for manufacturing, assembling, maintaining, and repairing the vehicles. The vehicle design drawings can further include assembly drawings, part drawings, wiring diagrams, body drawings, structural drawings, etc. Vehicle design drawings can be provided in the format of image files in the format of JPEG (Joint Photographic Experts Group), PNG (Portable Network Graphics), BMP (Bitmap), or TIFF (Tagged Image File Format), and can be provided in the form of computer-aided design (CAD) files in the format of DWG, DXF, STEP, or the like.

The first type table extracting module 12 can extract first type tables from a design drawing received through the vehicle design drawing input module 11. In some implementations, a “first type table” may refer to a table that is disposed inside the outermost edge line of a design drawing and is not shared with the outermost edge line of at least one modification design drawing. In contrast, a “second type table” may refer to a table that is shared with the outermost edge line of at least one modification design drawing.

The first type table extracting module 12 can extract first type tables from a design drawing, using a contour algorithm. Specifically, the first type table extracting module 12 can first binarize the design drawing to find the boundaries of the first type tables in the design drawing. For example, the binarization can be performed through thresholding or adaptive thresholding.

In some implementations, the first type table extracting module 12 can detect contours in the binarized design drawing, and extract contours satisfying a specific condition (for example, a specific size range condition or a specific shape condition) to extract only the contours of the first type tables from the detected contours. In some implementations, the first type table extracting module 12 can use a well-known edge detection algorithm to detect contours.

In design drawings, information may be represented in the form of a single table, and information may also be represented in the form of a plurality of tables. For example, in an assembly drawing, in order to represent the coupling relations of a variety of parts for a vehicle to be coupled, two tables may be used, and a line may be drawn between the cells of one table and the cells of another table. In this example, the device 10 for extracting information in a design drawing can use the first type table duplication removal module 13 to stop duplicated tables from being extracted.

The first type table duplication removal module 13 can detect child tables corresponding to child relationships with first type tables, from the first type tables extracted by the first type table extracting module 12, and remove the child table as duplicated tables. Referring to FIG. 2, from an assembly drawing D including two tables in which the coupling relationship between them is expressed by lines, the whole including the two tables should be extracted, and each of the two tables should be blocked from being extracted. In this example, when the whole including the two tables is referred to as a first type table (particularly, a parent table PT), each of the two tables may be referred to as a child table CT. The first type table duplication removal module 13 may leave parent tables PT representing complete information in the design drawing, as extracted, and remove child tables CT corresponding to portions of the parent tables and representing incomplete information even though they are extracted.

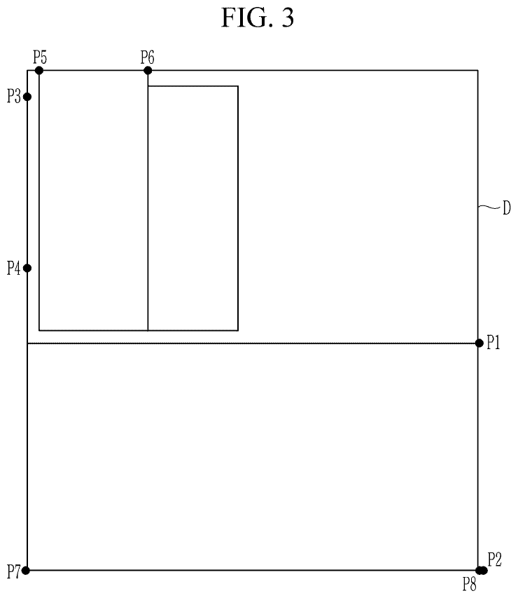

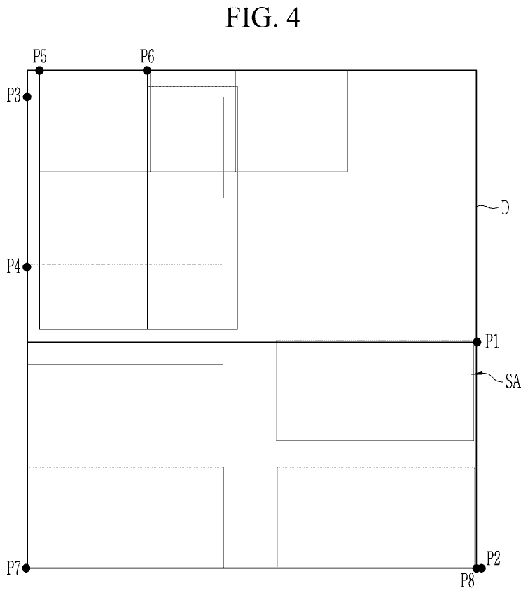

In some implementations, referring to FIGS. 3 and 4, the first type table duplication removal module 13 may designate a plurality of measurement points P1 to P8 in an image representing an extracted first type table. The plurality of measurement points P1 to P8 may be determined by analyzing the design drawing D, in consideration of points where outlines meet, points determined to make it easy to distinguish elements constituting the design drawing D, points derived by a predetermined algorithm, points determined experimentally, and the like. The number and positions of measurement points may be determined in various ways. Subsequently, the first type table duplication removal module 13 may designate a plurality of single table areas SA based on the plurality of measurement points P1 to P8. The sizes of the single table areas SA may be a first size determined in advance according to a specific implementation purpose or implementation environment. In some implementations, the first size may be set to the size of an already extracted first type table; however, the scope of the present invention is not limited thereto. The first type table duplication removal module 13 may check the extracted first type tables, using the plurality of single table areas SA, thereby detecting child tables. In other words, the first type table duplication removal module 13 may check the plurality of single table areas SA for identicalness while vertically or horizontally moving them on another extracted first type table, and determine another extracted first type table as a child table when identicalness is maintained until the number of movements reaches a predetermined value.

In other words, for example, in FIG. 2, when a first table corresponding to a parent table PT, a second table corresponding to a child table CT, and a third table irrelevant to the child table CT have been extracted, the second table may be set as a single table area SA. Then, the size of single table areas SA may be set to the size of the second table. Each single table area SA may be checked for identicalness while being moved in the state where the single table area overlaps the first table and the third table. First, in the case of the third table, the single table areas SA may be checked for identicalness while being moved on the third table, and since there is no identical area, the check on the third table may be terminated. Next, in the case of the first table, the single table areas SA may be checked for identicalness while being moved on the first table, and since an identical area would be detected, the second table corresponding to a single table area SA may be removed as a table that is a duplicate of a portion of the first table.

In some implementations, referring to FIGS. 3 to 5, the first type table duplication removal module 13 may designate a plurality of measurement points P1 to P8 in an image representing an extracted first type table. Subsequently, the first type table duplication removal module 13 may designate a plurality of single table areas SA based on the plurality of measurement points P1 to P8, respectively. The sizes of the single table areas SA may be a first size determined in advance according to a specific implementation purpose or implementation environment. Next, the first type table duplication removal module 13 may designate a plurality of crop areas CA1 and CA2 by cropping the plurality of single table areas SA at a predetermined ratio. The sizes of the crop areas CA1 and CA2 may be a predetermined second size. In some implementations, the second size may be set to a size obtained by dividing the smallest size of the extracted first type tables by n (where n is an integer equal to or greater than 2); however, the scope of the present invention is not limited thereto. In some implementations, the plurality of crop areas CA1 and CA2 may have a size obtained by cropping the plurality of single table areas SA at a ratio of one-third. The first type table duplication removal module 13 may check the extracted first type tables, using the plurality of crop areas CA1 and CA2, thereby detecting child tables. In other words, the first type table duplication removal module 13 may check the plurality of crop areas CA1 and CA2 for identicalness while vertically or horizontally moving them on another extracted first type table, and determine another extracted first type table as a child table when identicalness is maintained until the number of movements reaches a predetermined value.

In other words, for example, in FIG. 2, when a first table corresponding to a parent table PT, a second table corresponding to a child table CT, and a third table irrelevant to the child table CT have been extracted, an area obtained by cropping the second table at a ratio of one-third may be set as the crop area CA1. Then, the size of the crop area CA1 may be set to one-third of the size of the second table. The crop area CA1 may be checked for identicalness while being moved in the state where the single table area overlaps the first table and the third table. First, in the case of the third table, the crop area CA1 may be checked for identicalness while being moved on the third table, and since there is no identical area, the check on the third table may be terminated. Next, in the case of the first table, the crop area CA1 may be checked for identicalness while being moved on the first table, and since an identical area would be detected, the second table including the crop area CA1 may be removed as a table that is a duplicate of a portion of the first table.

Since tables that are determined as child tables as described above represent incomplete information, they may be removed. Accordingly, it is possible to extract only tables representing complete information from vehicle design drawings, depending on the types of the drawings. Therefore, the extraction accuracy can increase, and it is possible to lower the noise detection rate, and furthermore, it is possible to automate the task of correctly extracting information in design drawings without the need for human check on whether it is a parent table or a child table.

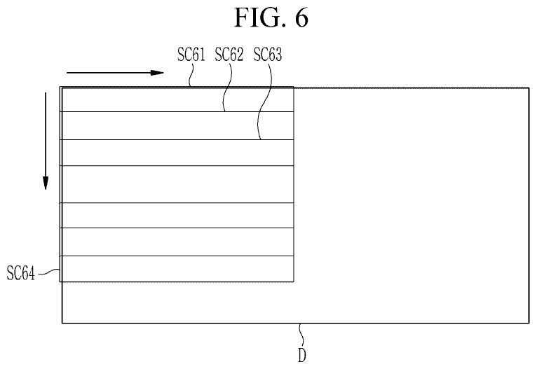

Referring to FIG. 6, as described above, check areas that may correspond to the crop areas CA1 and CA2 and may also correspond to the single table areas SA may be checked for identicalness while being moved vertically downward on an extracted first type table. Specifically, the first type table duplication removal module 13 may set a check area at a first position SC61, check for identicalness, move the check area to a second position SC62 when there is no identicalness, and then check for identicalness, and may repeat this operation until the check area reaches a third position SC63 and a fourth position SC64. The number of such repetitions or the distance over which the check area moves may be appropriately set depending on a specific implementation purpose or implementation environment.

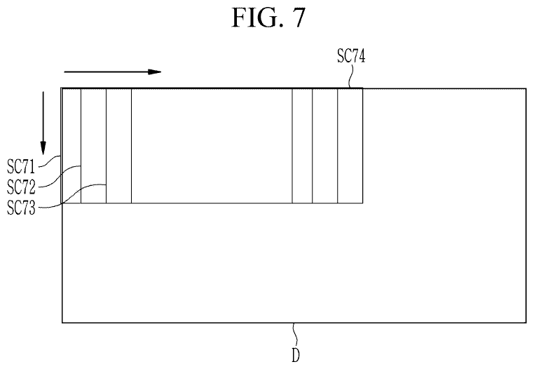

Subsequently, referring to FIG. 7, as described above, check areas that may correspond to the crop areas CA1 and CA2 and may also correspond to the single table areas SA may be checked for identicalness while being moved horizontally in the right direction on an extracted first type table. Specifically, the first type table duplication removal module 13 may set a check area at a first position SC71, check for identicalness, move the check area to a second position SC72 when there is no identicalness, and then check for identicalness, and may repeat this operation until the check area reaches a third position SC73 and a fourth position SC74. The number of such repetitions or the distance over which the check area moves may be appropriately set depending on a specific implementation purpose or implementation environment.

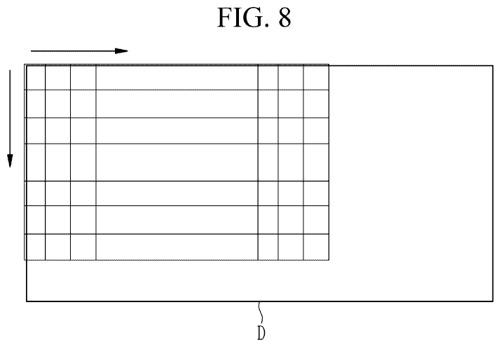

Then, referring to FIG. 8, it is shown that a process of checking a check area for identicalness while vertically moving it according to a predetermined number of times and a predetermined movement interval and checking the check area for identicalness while horizontally moving it according to a predetermined number of times and a predetermined movement interval by the combination of the operations of FIGS. 6 and 7 is repeated, and the order of the horizontal and vertical movements may be appropriately set according to a specific implementation purpose or implementation environment.

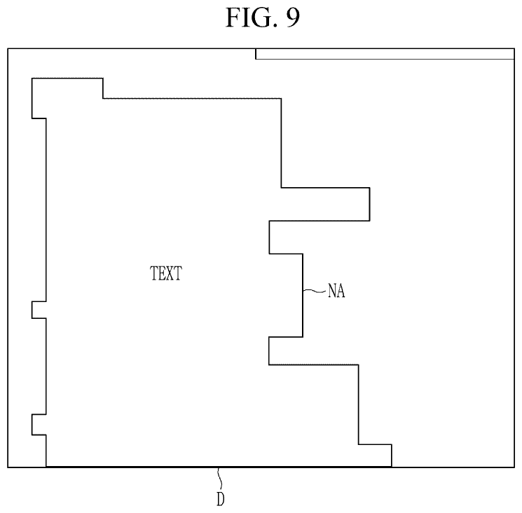

FIG. 9 is a drawing for explaining an operation example of the note area extracting module.

Referring to FIGS. 1 and 9 together, the note area extracting module 14 may extract a note area in a design drawing D. In note areas, texts are written, and it is general for design drawings to have no boundaries separating note areas. The note area extracting module 14 may extract a note area NA by repeatedly using an erode kernel and a dilate kernel for an area in a design drawing D in which text is written.

Specifically, the note area extracting module 14 may remove rectangular areas, i.e., tables and some portions of images from a design drawing D, using a contour algorithm, a morphological operation, or the like. After removing the rectangular areas, the note area extracting module 14 may further remove figure areas, using a contour algorithm, a morphological operation, or the like. Thereafter, the note area extracting module 14 may perform masking by expanding a black area, repeatedly using the erode kernel and the dilate kernel, and detect the location of the expanded area by a filter and a contour operation, and crop off and store note areas NA.

Erosion is an operation that reduces the boundaries of objects, and the kernel may visit every pixel while moving, and only when there is a portion completely overlapping the kernel, the original pixels may be preserved, otherwise, the pixels may be removed. Dilation is an operation of expanding boundaries of objects as opposed to erosion, and the kernel may visit every pixel while moving, and when there is at least one portion overlapping the kernel, corresponding pixels may be increased.

In some implementations, the note area extracting module 14 may expand black areas of text spaced apart by repeatedly performing erosion using an erode kernel (a 13-by-11 matrix) 20 times and repeatedly performing dilation using a dilate kernel (a 11-by-11 matrix) 40 times, and repeatedly performing erosion using the erode kernel (a 13-by-11 matrix) 25 times, thereby generating a single black mass. Next, the note area extracting module 14 may convert the result into a gray scale image, and check the edge area through a canny filter. Subsequently, the note area extracting module 14 may specify areas through a contour algorithm, and sort the specified areas by size such that they are arranged in order from the largest, and crop off and store the specified areas.

As described above, by the note area extracting module, areas where texts that are difficult to specify the exact boundaries are gathered since there are no boundaries shown can be precisely extracted.

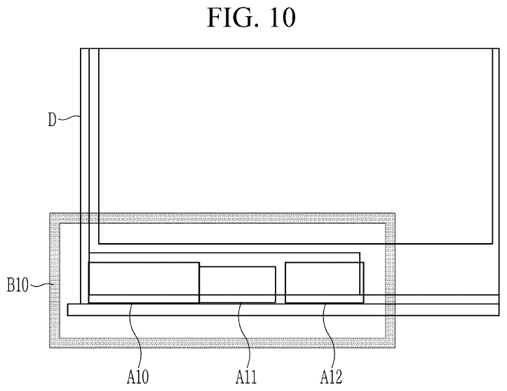

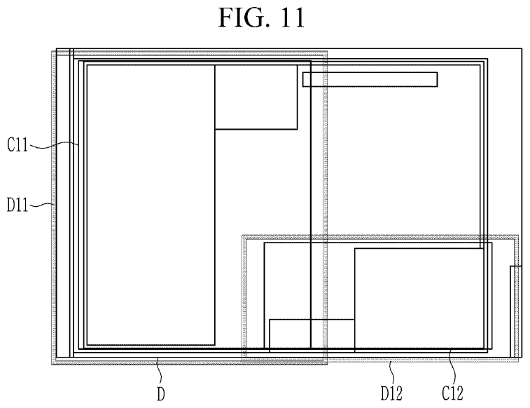

FIGS. 10 and 11 are drawings for explaining an operation example of a second type table extracting module.

Referring to FIG. 1, and FIGS. 10 and 11 together, the second type table extracting module 15 may extract second type tables shared with the outermost edge line of at least one modification design drawing D, from a design drawing D on which first type table extraction has been completed. When a plurality of second type table sharing one outermost edge line is extracted, the second type table extracting module 15 may extract them as one or separately extract them depending on whether the height differences between them exceed a predetermined value.

As shown in FIG. 10, when one table is extracted separately into three tables A10, A11, and A12, the second type table extracting module may calculate the height differences of the three tables A10, A11, and A12. When the height differences of the three tables A10, A11, and A12 are smaller than a predetermined reference value, the second type table extracting module may consider the three tables A10, A11, and A12 as constituting one table, and eventually extract them into a signal table B10.

On the other hand, as shown in FIG. 11, when two tables c11 and C12 are extracted separately, the second type table extracting module may calculate the height difference between the two tables c11 and C12, and when the height difference is equal to or greater than the predetermined reference value, the second type table extracting module may consider the two tables c11 and C12 as constituting two tables as extracted, and extract them into two tables D11 and D12.

In this way, by the second type table extracting module, it is possible to increase the accuracy of extraction of tables shared with the outermost edge line of at least one modification design drawing.

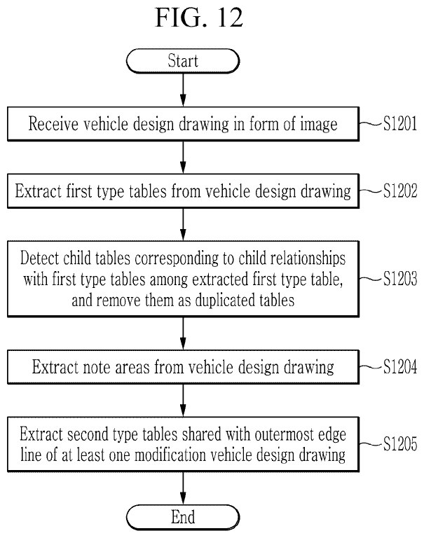

FIG. 12 is a flow chart for explaining a method for extracting information in a design drawing.

Referring to FIG. 12, a method for extracting information in a design drawing may include a step of receiving a design drawing in the form of an image (S1201), a step of extracting first type tables from the design drawing (S1202), a step of detecting child tables corresponding to child relationships with the first type tables among the extracted first type tables and removing the child tables as duplicated tables (S1203), a step of extracting note areas from the design drawing (S1204), and a step of extracting second type tables shared with the outermost edge line of at least one modification design drawing, from the design drawing on which first type table extraction has been completed (S1205).

As for more specific details of the method for extracting information in the design drawing, the description of the exemplary implementations described in this specification may be referred to and applied, so a redundant description thereof will not be made herein.

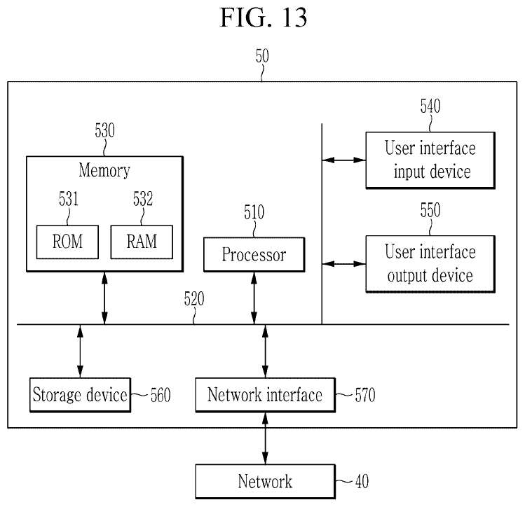

FIG. 13 is a drawing for explaining a computing device.

Referring to FIG. 13, the device and method for extracting information in a design drawing may be implemented using a computing device 50.

The computing device 50 may include at least one of a processor 510, a memory 530, a user interface input device 540, a user interface output device 550, and a storage device 560 that perform communication through a bus 520. The computing device 50 may also include a network interface 570 that is electrically connected to a network 40. The network interface 570 may transmit or receive signals to or from other entities via the network 40.

The processor 510 may be implemented with various types, such as a micro controller unit (MCU), an application processor (AP), a central processing unit (CPU), a graphic processing unit (GPU), a neutral processing unit (NPU), a quantum processing unit (QPU), and the like, and may be an arbitrary semiconductor device that executes instructions stored in the memory 530 or the storage device 560. The processor 510 may be configured to implement the functions and methods described above with respect to FIG. 1 to FIG. 12.

The memory 530 and the storage device 560 may include various forms of volatile or non-volatile storage media. For example, the memory may include a read-only memory (ROM) 531 and a random access memory (RAM) 532. In some implementations, the memory 530 may be located inside or outside the processor 510, and the memory 530 may be coupled to the processor 510 through various known means.

In some implementations, at least some components or functions of the device and method for extracting information in a design drawing may be implemented as programs or software which is executed in the computing device 50, and the programs or software may be stored in computer-readable media. Specifically, a computer-readable medium may be a medium containing a program for making the computer including the processor 510 for executing programs or instructions stored in the memory 530 or the storage device 560 execute steps included in the method for extracting information in a design drawing.

In some implementations, at least some components or functions of the device and method for extracting information in a design drawing may be implemented using hardware or circuits of the computing device 50 or may be implemented with separate hardware or circuits electrically connectable to the computing device 50. According to the exemplary implementations described so far, it is possible to extract tables and note areas containing information from vehicle design drawings. Further, since it is possible to extract only tables representing complete information from vehicle design drawings, depending on the types of the drawings, the extraction accuracy can increase, and it is possible to lower the noise detection rate, and furthermore, it is possible to automate the task of correctly extracting information in design drawings without the need for human check on whether it is a parent table or a child table. Furthermore, areas where texts that are difficult to specify the exact boundaries are gathered since there are no boundaries shown can be precisely extracted, and it is possible to increase the accuracy of extraction of tables shared with the outermost edge line of at least one modification design drawing.

What is claimed is:

1. A device for extracting information from a design drawing, the device comprising:
a vehicle design drawing input module, implemented using one or more computing devices, configured to receive a design drawing of a vehicle as an image;
a first type table extracting module, implemented using one or more computing devices, configured to extract one or more first type tables from the design drawing; and
a first type table duplication removal module, implemented using one or more computing devices, configured to:
detect, from the extracted one or more first type tables, one or more child tables corresponding to one or more child relationships with the one or more first type tables, and
remove the one or more child tables as duplicated tables.

2. The device according to claim 1, wherein the first type table duplication removal module is configured to:
designate a plurality of measurement points in an image of each of the extracted one or more first type tables,
designate a plurality of single table areas based on the plurality of measurement points, and
detect the one or more child tables based on the one or more extracted first type tables using the plurality of single table areas.

3. The device according to claim 2, wherein the first type table duplication removal module is configured to:
identify an identical area from each of the plurality of single table areas by moving each area vertically or horizontally on another extracted first type table, and
determine another extracted first type table as the child table based on identicalness being maintained until a number of movements reaches a predetermined value.

4. The device according to claim 2, wherein the first type table duplication removal module is configured to:
designate a plurality of crop areas obtained by cropping the plurality of single table areas at a predetermined ratio, and
detect the child tables based on the one or more extracted first type tables using the plurality of crop areas.

5. The device according to claim 4, wherein the first type table duplication removal module is configured to:
identify an identical area in the plurality of crop areas by moving each area vertically or horizontally on another extracted first type table, and
determine another extracted first type table as the child table based on identicalness being maintained until a number of movements reaches a predetermined value.

6. The device according to claim 4, wherein the plurality of crop areas has a size obtained by cropping the plurality of single table areas at a ratio of one-third.

7. The device according to claim 1, further comprising:
a note area extracting module, implemented using one or more computing devices, configured to extract one or more areas from the design drawing.

8. The device according to claim 7, wherein the note area extracting module is configured to extract the one or more note areas by repeatedly using an erode kernel and a dilate kernel on one or more areas in the design drawing where text is written.

9. The device according to claim 1, further comprising:
a second type table extracting module, implemented using one or more computing devices, configured to extract, from the design drawing on which the first type table extraction has been completed, one or more second type tables shared with the outermost edge line of at least one modification design drawing.

10. The device according to claim 9, wherein the second type table extracting module is configured to, based on a plurality of second type tables sharing the outermost edge line being extracted, extract the plurality of second type tables into one or separately based on height differences between the plurality of second type tables exceeding a predetermined value.

11. A method for extracting information from a design drawing, the method comprising:
receiving a design drawing of a vehicle as an image;
extracting one or more first type tables from the design drawing;
detecting, from the extracted one or more first type tables, one or more child tables corresponding to one or more child relationships with the one or more first type tables; and
removing the one or more child tables as duplicated tables.

12. The method according to claim 11, wherein removing the one or more child tables as duplicated tables includes:
designating a plurality of measurement points in an image of each of the extracted one or more first type tables,
designating a plurality of single table areas based on the plurality of measurement points, and
detecting the one or more child tables based on the one or more extracted first type tables using the plurality of single table areas.

13. The method according to claim 12, wherein removing the one or more child tables as duplicated tables includes:
identifying an identical area from each of the plurality of single table areas by moving each area vertically or horizontally on another extracted first type table, and
determining another extracted first type table as the child table based on identicalness being maintained until a number of movements reaches a predetermined value.

14. The method according to claim 12, wherein removing the one or more child tables as duplicated tables includes:
designating a plurality of crop areas obtained by cropping the plurality of single table areas at a predetermined ratio, and
detecting the one or more child tables based on the one or more extracted first type tables using the plurality of crop areas.

15. The method according to claim 14, wherein removing the one or more child tables as duplicated tables includes:
identifying an identical area in the plurality of crop areas by moving each area vertically or horizontally on another extracted first type table, and
determining another extracted first type table as the child table based on identicalness being maintained until a number of movements reaches a predetermined value.

16. The method according to claim 14, wherein the plurality of crop areas has a size obtained by cropping the plurality of single table areas at a ratio of one-third.

17. The method according to claim 11, further comprising:
extracting one or more note areas from the design drawing.

18. The method according to claim 17, wherein extracting the one or more note areas includes extracting the one or more note areas by repeatedly using an erode kernel and a dilate kernel on areas in the design drawing where text is written.

19. The method according to claim 11, further comprising:
extracting, from the design drawing on which the first type table extraction has been completed, one or more second type tables shared with the outermost edge line of at least one modification design drawing.

20. The method according to claim 19, wherein extracting the one or more second type tables includes extracting a plurality of second type tables sharing the outermost edge line into one or separately based on height differences between the plurality of second type tables exceeding a predetermined value.
